(19) United States
(12) Patent Application Publication
(10) Pub. No.: US 2005/0045105 A1
(43) Pub. Date: Mar. 3, 2005

(54) Holder for multiple substrates and chamber with the same

(75) Inventors: Jung Hwan Choi, Seoul (KR); Kyoung Woong Park, Seoul (KR)

Correspondence Address: MARGER JOHNSON & MCCOLLOM, P.C., 1030 SW MORRISON STREET, PORTLAND, OR, 97205, US

(73) Assignee: Jusung Engineering Co., Ltd., Kwangju-shi (KR)

(21) Appl. No.: 10/927,706

(22) Filed: Aug. 27, 2004

(30) Foreign Application Priority Data
Aug. 27, 2003 (KR) 10-2003-0059527

(51) Int. Cl. C23C 16/00

(52) U.S. Cl. 118/728

(57) ABSTRACT

The present invention relates to a substrate holder for performing the same or different processes on a plurality of substrates independently of each other in a single chamber and a chamber mounted with the same. According to the present invention, there is provided a substrate holder for fixing a plurality of substrates. The substrate holder comprises a plurality of nozzles for injecting curtain gas for separating the plurality of the substrates from each other.

### BACKGROUND OF THE INVENTION

This application claims priority from Korean Patent Application No. 2003-0059527, filed on Aug. 27, 2003, in the Korean Intellectual Property Office, the disclosure of which is incorporated herein in its entirety by reference.

1. Field of Invention

The present invention relates to a substrate holder for fixing a plurality of substrates and a chamber mounted with the same, and more particularly, to a substrate holder for performing the same or different processes on a plurality of substrates independently of each other in a single chamber and a chamber mounted with the same.

2. Description of the Prior Art

As shown in FIGS. 1a and 1b, a conventional substrate holder comprises a main substrate holder 10, secondary substrate holders 11 which are provided in the main substrate holder 10 and onto which substrates are mounted, lift pins 12 installed under the main substrate holder 10 in order to vertically lift the main substrate holder 10, and pumping holes 9 for exhaust which are formed in the main substrate holder or the secondary substrate holders. Generally, when it is necessary to exchange substrates according to the progress of a process, the substrates mounted on the secondary substrate holders are exchanged by using a robot arm and fingers (not shown) after the main substrate holder 10 is lifted at a predetermined height.

If process gases are supplied onto the respective substrates, the process gases may interfere with each other. Accordingly, contamination or non-uniform deposition may occur on the substrates, particularly edge portions of the substrates. Particularly, when multilayer deposition is performed on a plurality of substrates in such a configuration by using at least two process gases, it is often necessary to shift the substrates to another chamber according to the progress of the deposition process. Thus, there is a problem in that the exchange of the substrates delays the deposition process.

### SUMMARY OF THE INVENTION

Accordingly, the present invention is conceived to solve the aforementioned problems in the prior art. An object of the present invention is to provide a substrate holder which makes it possible to independently perform an individual process controllable for each of a plurality of substrates, and a chamber mounted with the same.

According to an aspect of the present invention for achieving the object, there is provided a substrate holder for fixing a plurality of substrates. The substrate holder comprises a plurality of nozzles for injecting curtain gas for separating the plurality of the substrates from each other.

The substrate holder may further comprise a partition for separating the plurality of the substrates from each other for independently performing processes.

Preferably, the plurality of the nozzles may be formed adjacent to the partition or formed around the respective substrates.

The substrate holder may further comprise a main substrate holder; secondary substrate holders provided in the main substrate holder for fixing the substrates, respectively; and pumping holes for exhaust formed in the main substrate holder or the secondary substrate holders.

According to another aspect of the present invention for achieving the object, there is provided a chamber, which comprises the substrate holder as described above; a lower chamber, to a bottom of which the substrate holder is rotatably mounted; a chamber lid for covering the lower chamber; and a plurality of injectors for injecting process gas onto the respective substrates fixed on the substrate holder.

According to an additional aspect of the present invention for achieving the object, there is provided a chamber, which comprises a substrate holder for fixing a plurality of substrates; a lower chamber, to a bottom of which the substrate holder is rotatably mounted; a chamber lid for covering the lower chamber; a plurality of injectors for injecting process gas onto the respective substrates fixed on the substrate holder; and a plurality of nozzles for injecting curtain gas for separating the plurality of the substrates from each other.

The substrate holder may comprise a partition for separating the plurality of the substrates from each other. Preferably, the partition is lower than a sidewall of the lower chamber.

Preferably, a seal may be provided between an upper end of the partition and the chamber lid.

More preferably, the nozzles may be installed in the substrate holder or the chamber lid.

### BRIEF DESCRIPTION OF THE DRAWINGS

The above and other objects, features and advantages of the present invention will become apparent from the following description of preferred embodiments given in conjunction with the accompanying drawings, in which:

FIG. 1a is a plane view of a conventional substrate holder;

FIG. 1b is a sectional side view of the substrate holder taken along a line A-A of FIG. 1a;

FIG. 2a is a plane view of a substrate holder according to an embodiment of the present invention;

FIG. 2b is a partially cutaway perspective view of a chamber according to an embodiment of the present invention mounted with the substrate holder of FIG. 2a as seen from above;

FIG. 3 is a perspective view of a lower chamber, as seen from above, and a chamber lid, as seen from below, of a chamber according to another embodiment of the present invention;

FIG. 4a is a perspective view of a lower chamber, as seen from above, and a chamber lid, as seen from below, of a chamber according to an additional embodiment of the present invention using the lower chamber of FIG. 2b;

FIG. 4b is a detail view of a curtain gas supplier of the chamber of FIG. 4a;

FIG. 5 is a perspective view of a lower chamber, as seen from above, and a chamber lid, as seen from below, of a chamber according to a still additional embodiment of the present invention using the lower chamber of FIG. 2b;

FIGS. 6 and 7 are perspective views of main substrate holders of further embodiments according to the present invention; and

FIG. 8 is a partially cutaway perspective view of a lower chamber of a still further embodiment according to the present invention.

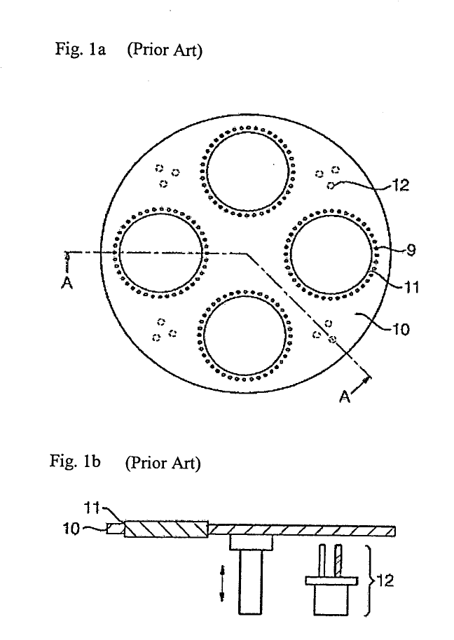

### DETAILED DESCRIPTION OF THE PREFERRED EMBODIMENT

Hereinafter, preferred embodiments of a substrate holder and a chamber according to the present invention will be described in detail with reference to the accompanying drawings.

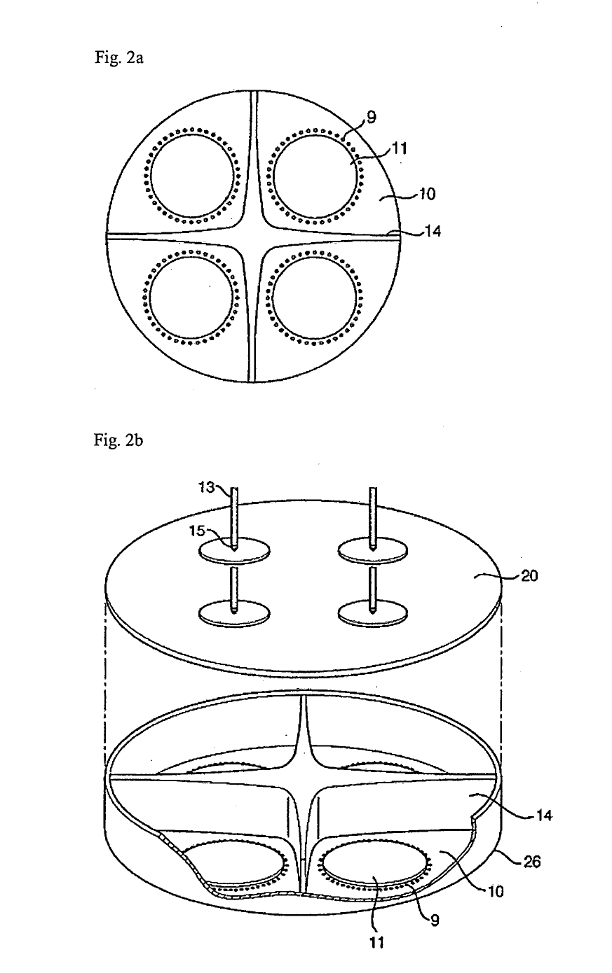

FIG. 2a is a plane view of a substrate holder according to an embodiment of the present invention. FIG. 2b is a perspective view of a chamber mounted with the substrate holder of FIG. 2a.

A main substrate holder 10 is provided with secondary substrate holders 11 for fixing a plurality of substrates, for example four substrates as shown in the figures, respectively, and a partition 14 for separating the substrates from each other. Such a partition 14 causes different processes not to interfere with each other when the different processes are independently performed on the respective substrates. Such a substrate holder is rotatably mounted to a bottom of a lower chamber 26. The lower chamber 26, which is covered with a chamber lid 20, provides an inner space of the chamber. The chamber lid is mounted with injectors 13 for supplying process gas into the chamber. Particularly, as shown in FIG. 2b, if a seal is provided between an upper end of the partition 14 and the chamber lid 20, it is possible to separately control a temperature for the respective substrates. Thus, individual spaces which the plurality of the substrates occupy respectively, can be separated from each other so that the different processes are independently performed on the respective substrates.

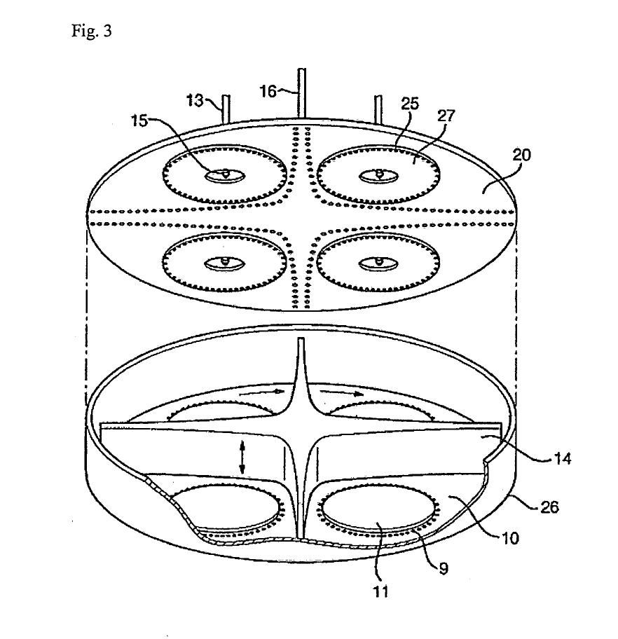

Referring to FIG. 3, since the partition 14 is somewhat lower in height than a sidewall of the lower chamber, there is provided a gap between the upper end of the partition and the chamber lid 20. With the chamber lid 20 being sealed with the lower chamber 26, the substrate wherein the independent process performed in the chamber is completed is unloaded for the next process, and then, a new substrate is loaded in the chamber. Although a mechanism for loading and/or unloading the substrate is not shown in figures, the substrate is generally loaded and/or unloaded through a window formed in the sidewall of the lower chamber. To this end, it is necessary to vertically move and rotate the main substrate holder. The gap functions to prevent the upper end of the partition 14 attached to main substrate holder from colliding with the chamber lid 20 when the main substrate holder vertically moves with the chamber lid covering the lower chamber. In addition, since the partition 14 rotates along with the main substrate holder 10 when the main substrate holder 10 rotates, the partition 14 should be spaced apart by a predetermined gap from the sidewall of the lower chamber 26. However, in such a configuration, it is difficult to independently perform the respective processes on the plurality of the substrates. That is, since the process gases supplied to respective substrates interfere with each other through the predetermined gaps between the partition and the chamber lid and between the partition and the sidewall of the lower chamber, it causes the substrates to be contaminated. In order to prevent the contamination, the chamber lid is provided with nozzles 25 for injecting curtain gas into the lower chamber so that the gaps are blocked by the curtain gas as shown in FIG. 3, and thus, the individual spaces for the processes are independently maintained.

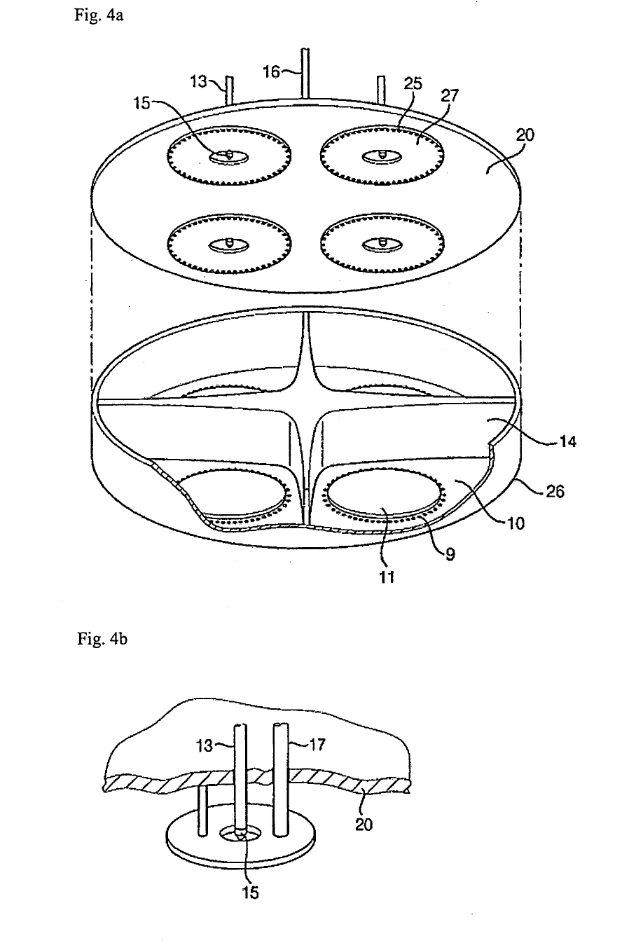

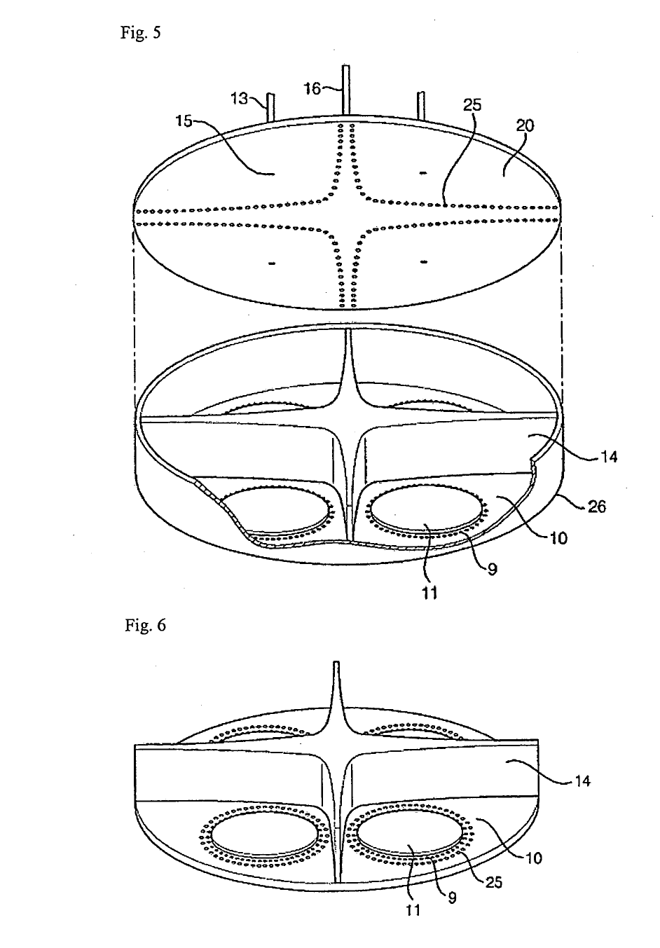

FIGS. 4a, 4b and 5 are schematic perspective views of two embodiments of a chamber according to the present invention which comprises a chamber lid and a lower chamber and causes respective processes to be independently performed on a plurality of substrates. Referring to FIG. 4a, the chamber lid 20 is mounted with curtain gas injectors 27, which are positioned corresponding to the respective substrates. Each of the curtain gas injectors 27 is formed with the nozzles 25 for injecting, for example, argon (Ar) gas into the chamber. The curtain gas injector 27, which is shaped like a showerhead, is connected to a secondary supply line 17 for supplying the curtain gas, which branches from a main supply line 16. The nozzles 25 of each of the curtain gas injectors 27 inject the argon gas around the corresponding substrate. In the embodiment shown in FIG. 5, a chamber lid is provided with nozzles for injecting the curtain gas around the partition 14. The nozzles 25 are installed in the chamber lid 20 along the shape of the partition, and inject the argon curtain gas between the substrates in the lower chamber in order for the process gases not to interfere with each other.

The argon curtain gas functions to minimize the interference of the process gases which are supplied onto the respective substrates which may be different from each other. The argon curtain gas is used so as to separate the inner space of the chamber into the individual spaces which the plurality of the substrates occupy respectively, and thus, can make an environment corresponding thereto when it is difficult to physically completely separate the inner space of the chamber. That is, if the down flow of the argon curtain gas is formed, the argon curtain gas flows between the substrates and functions like as a curtain. Therefore, the respective process gases supplied through the injector exist within the regions formed by the down flow of the argon curtain gas, which makes it possible to perform the independent processes on the respective substrates. When the curtain gas is employed along with the partition, the above effect can be more improved. In the meantime, since only the curtain gas without the partition can somewhat secure the independency of the respective substrates in the chamber, it is possible to separate the substrates from each other only by means of the curtain gas without installing the partition on the main substrate holder.

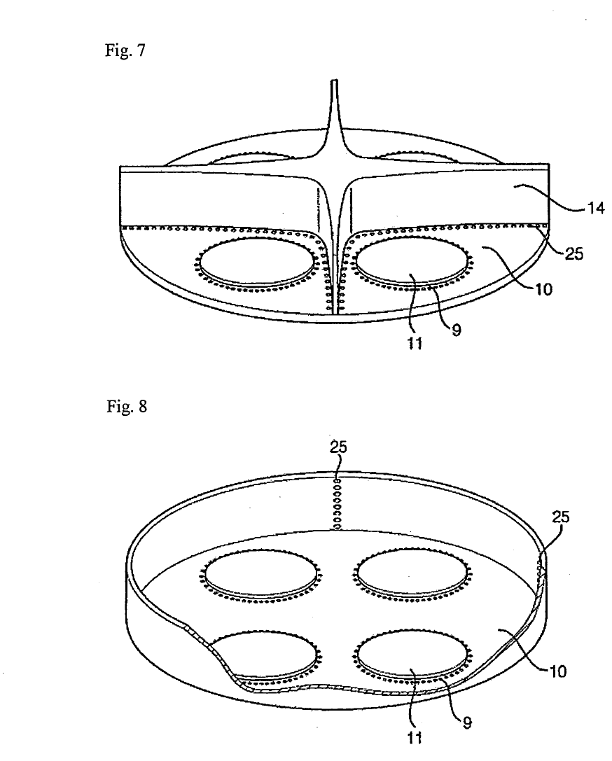

FIGS. 6 and 7 show further embodiments of the present invention, comprising a main substrate holder provided with a partition and nozzles for supplying argon curtain gas together. A substrate holder of the embodiment shown in FIG. 6 is provided with the main substrate holder 10 including the partition 14 and a plurality of the nozzles 25 around each substrate fixed to each secondary substrate holder. A substrate holder of the embodiment shown in FIG. 7 is provided with the main substrate holder 10 including the partition 14 and a plurality of the nozzles 25 formed in the main substrate holder along the shape of the partition 14. In the meantime, since only the curtain gas without the partition can somewhat secure the independency of the respective substrates, it is possible to separate the substrates from each other only by means of the curtain gas without installing the partition on the main substrate holder. If the argon curtain gas is injected through the nozzles 25 in each case of the embodiments, the process gases are supplied within respective regions formed by the argon curtain gas, so that the independent processes may be performed on the respective substrates.

Referring to FIG. 8 which shows a still further embodiment of the present invention, nozzles are installed in the inner sidewall of the chamber and not a main substrate holder or a chamber lid. In such an embodiment, the processes are also independently performed on a plurality of the substrates, respectively. The substrate holder and the chamber of the present invention constructed as above cause the processes to be independently performed on a plurality of semiconductor substrates. Thus, a multilayer deposition process may be easily performed in a single chamber, and the process gas may be widely selected.

If the partition and the main substrate holder rotate together as in the embodiments of the present invention, since a time for exchanging the substrates fixed onto the secondary substrate holders may be reduced, a total yield increases. In addition, since the existing configuration of the substrate holder is not largely modified, costs for manufacturing the substrate holder and the chamber of the present invention may be effectively saved.

Although the substrate holder comprising the main substrate holder, the secondary substrate holders, and the pumping holes formed in the main substrate holder is described as the embodiments of the present invention up to now, the present invention is not limited thereto but is defined by the appended claims. It will be apparent that those skilled in the art can make various modifications and changes thereto within the scope of the invention defined by the claims. Therefore, the true scope of the present invention should be defined by the technical spirit of the appended claims.

1. A substrate holder for fixing a plurality of substrates, comprising:
a plurality of nozzles for injecting curtain gas for separating the plurality of the substrates from each other.

2. The substrate holder as claimed in claim 1, further comprising a partition for separating the plurality of the substrates from each other.

3. The substrate holder as claimed in claim 2, wherein the plurality of the nozzles are formed adjacent to the partition.

4. The substrate holder as claimed in claim 1, wherein the plurality of the nozzles are formed around the respective substrates.

5. The substrate holder as claimed in claim 1, comprising:
a main substrate holder;
secondary substrate holders provided in the main substrate holder, the secondary substrate holders fixing the substrates, respectively; and
pumping holes for exhaust formed in the main substrate holder or the secondary substrate holders.

6. A chamber, comprising:
the substrate holder as claimed in any one of claims 1 to 5;
a lower chamber, to a bottom of which the substrate holder is rotatably mounted;
a chamber lid for covering the lower chamber; and
a plurality of injectors for injecting process gas onto the respective substrates fixed on the substrate holder.

7. A chamber, comprising:
a substrate holder for fixing a plurality of substrates;
a lower chamber, to a bottom of which the substrate holder is rotatably mounted;
a chamber lid for covering the lower chamber;
a plurality of injectors for injecting process gas onto the respective substrates fixed on the substrate holder; and
a plurality of nozzles for injecting curtain gas for separating the plurality of the substrates from each other.

8. The chamber as claimed in claim 7, wherein the substrate holder comprises a partition for separating the plurality of the substrates from each other.

9. The chamber as claimed in claim 8, wherein the partition is lower than a sidewall of the lower chamber.

10. The chamber as claimed in claim 8 or 9, wherein a seal is provided between an upper end of the partition and the chamber lid.

11. The chamber as claimed in claim 8 or 9, wherein the nozzles are installed in the substrate holder.

12. The chamber as claimed in claim 8 or 9, wherein the nozzles are installed in the chamber lid.
